(19) United States
(12) Patent Application Publication
(10) Pub. No.: US 2024/0276765 A1
(43) Pub. Date: Aug. 15, 2024

(54) ROBOT ARM, DUMMY REMOVAL SYSTEM INCLUDING THE SAME, AND METHOD OF DRIVING THE SAME

(71) Applicant: Samsung Display Co., LTD., Yongin-si (KR)

(72) Inventors: Hyoung Joo KIM, Yongin-si (KR); Jong Hee LIM, Yongin-si (KR); Eun Su JUN, Yongin-si (KR); Il Young JEONG, Yongin-si (KR); Hak Min KIM, Yongin-si (KR)

(21) Appl. No.: 18/463,106

(22) Filed: Sep. 7, 2023

(30) Foreign Application Priority Data
Feb. 9, 2023 (KR) 10-2023-0017313

(51) Int. Cl. H10K 59/12; B25J 11/00; B25J 15/00; H10K 59/80; H10K 59/88; H10K 71/00

(52) U.S. Cl. CPC H10K 59/1201; B25J 11/0055; B25J 15/0028; H10K 59/873; H10K 59/8793; H10K 59/88; H10K 71/851

(57) ABSTRACT

A robot arm is provided that includes: a first gripper having a first contact surface; a second gripper having a second contact surface corresponding to the first contact surface and an opening in the second contact surface; and a stopper including a pin protruding toward the first gripper. The stopper is configured to pass through the opening in the second gripper. As provided are a dummy removal system including the robot arm and a method of driving the dummy removal system to remove a polarization structure of a display panel.

### CROSS-REFERENCE TO RELATED APPLICATION

This application claims priority to and the benefit of Korean Patent Application number 10-2023-0017313, filed on Feb. 9, 2023, the entire disclosure of which is incorporated herein by reference.

### BACKGROUND

### 1. Field

Aspects of embodiments of the present disclosure relate to a robot arm, a dummy removal system including the robot arm, and a method of driving the dummy removal system.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased. A display device generally includes a display panel configured to display an image.

A polarization structure (e.g., a polarization filter) may be provided on one surface of the display panel. The polarization structure may prevent external light from being reflected by the display device or may enhance the display quality of the display device.

During a process of fabricating the display panel, a portion of the polarization structure may be removed. However, because one surface of the polarization structure is adhesive (e.g., has adhesive on it), it is difficult to remove the polarization structure.

### SUMMARY

Embodiments of the present disclosure are directed to a robot arm capable of easily removing a polarization structure of a display panel, a dummy removal system including the robot arm, and a method of driving the dummy removal system.

A robot arm, according to an embodiment of the present disclosure, includes: a first gripper having a first contact surface; a second gripper having a second contact surface corresponding to the first contact surface and an opening in the second contact surface; and a stopper including a pin protruding toward the first gripper. The stopper is configured to pass through the opening in the second gripper.

The robot arm may further include: a first rotator connected to the first gripper; and a connector coupled to the first rotator such that a rotational direction of the connector is guided by the first rotator.

The second gripper may be connected to the connector.

The second gripper may be configured to rotate about the first rotator, and the pin may be arranged along a path along which the second gripper rotates.

The robot arm may further include: a second rotator coupled to the connector; and a cylinder configured to guide movement of the second rotator.

The stopper may be fixed to the first gripper.

The stopper may be configured to rotate in a direction opposite to a direction in which the second gripper rotates.

The second gripper may have an air outlet in the second contact surface.

A dummy removal system, according to an embodiment of the present disclosure, includes: a stage configured to receive a display panel, the display panel including a pixel component in a central portion thereof and a dummy around the pixel component, the dummy being cut from the display panel along a cutting line; and a robot arm including a first gripper configured to contact a first surface of the dummy, a second gripper configured to contact a second surface of the dummy, and a stopper configured to pass through an opening in the second gripper.

The display panel may include a display structure and a polarization structure on the display structure, and the polarization structure may include an adhesive layer, a polarization layer, and a passivation film sequentially stacked on each other.

The polarization structure may include a polarization film, and the dummy may include the adhesive layer, the polarization layer, and the passivation film.

The first surface may be an upper surface of the passivation film, and the second surface may be a lower surface of the adhesive layer. The first gripper may have a first contact surface for contacting the upper surface of the passivation film, and the second gripper may have a second contact surface for contacting the lower surface of the adhesive layer.

The robot arm may further include: a first rotator connected to the first gripper; and a connector coupled to the first rotator such that a rotational direction of the connector is guided by the first rotator. The second gripper may be connected to the connector.

The dummy removal system may further include: a second rotator coupled to the connector; and a cylinder configured to guide movement of the second rotator.

The stopper may include a pin protruding toward the first gripper. As a piston in the cylinder moves forward, the second gripper may move toward the first gripper, and as the piston in the cylinder moves backward, the second gripper may move toward the pin.

The display structure may include: a base substrate; a pixel circuit layer on the base substrate and including a thin-film transistor; a light-emitting-element layer connected to the thin-film transistor and including a light emitting element and an emission layer; and an encapsulation layer covering the light-emitting-element layer.

The cutting line may be more inside than one side end of the display structure.

A method of operating a dummy removal system including a robot arm, according to an embodiment of the present disclosure, includes: seating a display panel on a stage, the display panel including a pixel component in a central portion thereof and a dummy around the pixel component, the dummy being formed by cutting the display panel along a cutting line; a gripping operation including bringing a first surface of the dummy into contact with a first contact surface of a first gripper of the robot arm and bringing a second surface of the dummy into contact with a second contact surface of a second gripper of the robot arm; a second gripper supporting operation including moving the second gripper away from the first contact surface with the dummy attached to the second gripper; a stopper supporting operation including moving the second gripper through the stopper to support the dummy on a pin of the stopper and to remove the dummy from the second gripper; and a dummy removal operation including removing the dummy from the pin in a direction of gravity.

The robot arm may include: a first rotator connected to the first gripper; a connector coupled to the first rotator such that a rotational direction of the connector is guided by the first rotator, the second gripper being connected to the connector; a second rotator coupled to the connector; and a cylinder configured to guide movement of the second rotator. The gripping operation may include moving a piston in the cylinder forward.

Each of the second gripper supporting operation and the stopper supporting operation may include moving the piston in the cylinder backward.

### BRIEF DESCRIPTION OF THE DRAWINGS

FIG. 1 illustrates a display device according to an embodiment of the present disclosure.

FIG. 2 illustrates a dummy according to an embodiment of the present disclosure.

FIG. 3 is a sectional view of the display device shown in FIG. 1 taken along the line I-I′.

FIG. 4 illustrates a display panel cutting system according to an embodiment of the present disclosure.

FIG. 5 illustrates a dummy removal system according to an embodiment of the present disclosure.

FIG. 6 illustrates a robot arm according to an embodiment of the present disclosure.

FIG. 7 is a diagram illustrating a dummy supported on a second gripper.

FIGS. 8A to 8D are diagrams illustrating steps of a method of driving a dummy removal system according to an embodiment of the present disclosure.

FIG. 9 is a schematic view illustrating a robot arm according to an embodiment of the present disclosure.

FIG. 10 is a schematic view illustrating a robot arm according to another embodiment of the present disclosure.

FIG. 11 is a schematic view illustrating a robot arm according to another embodiment of the present disclosure.

### DETAILED DESCRIPTION

Hereinafter, embodiments of the present disclosure will be described, in detail, with reference to the attached drawings, such that those skilled in the art can easily implement the present disclosure. The present disclosure may be implemented in various forms and is not limited to the embodiments described herein.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the drawings, dimensions of the various elements, layers, etc. may be exaggerated for clarity of illustration. Also, in the drawings and disclosure that follows, portions, elements, components, or features of embodiments that are not related to or necessary for one of ordinary skill in the art to fully understand the present disclosure may be omitted to explain the aspects and features of the present disclosure more clearly.

The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Furthermore, the expression “being the same” may mean “being substantially the same”. In other words, the expression “being the same” may include a range (e.g., a tolerance range) that would be understood by those skilled in the art. The other expressions may also be expressions from which “substantially” has been omitted.

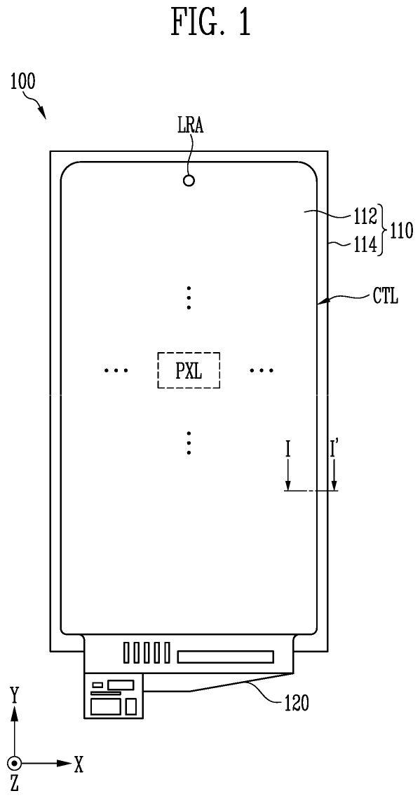

FIG. 1 illustrates a display device 100 according to an embodiment of the present disclosure.

Referring to FIG. 1, the display device 100, according to an embodiment of the present disclosure, may include a display panel 110 and a circuit substrate (or circuit board) 120.

The display panel 110 may include a pixel component (or pixel part) 112 in which a pixel PXL is disposed and a dummy 114 disposed around the pixel component 112 (e.g., in a peripheral area of the pixel component 112).

A plurality of pixels PXL may be disposed in the pixel component 112. For example, the plurality of pixels PXL may be disposed in the form of a matrix in the pixel component 112. For example, the plurality of pixels PXL may be disposed to have a PENTILE® structure or arrangement (e.g., an RGBG matrix, RGBG structure, or RGBG matrix structure) in the pixel component 112. PENTILE® is a duly registered trademark of Samsung Display Co., Ltd. A pad component configured to supply a signal (e.g., a data signal, a scan signal, or the like) to the pixels PXL may be disposed in the pixel component 112.

The pixel PXL is configured to display an image. For example, the pixel PXL may receive a scan signal and may receive a data signal in response to the scan signal having a turn-on level. The scan signal may be inputted into the pixel PXL through a scan line extending in (or through) the display panel 110 in a first direction (e.g., a transverse direction or an X-axis direction). The data signal may be inputted to the pixel PXL through a data line extending in (or through) the display panel 110 in a second direction (e.g., a longitudinal direction or a Y-axis direction). In an embodiment, a signal line configured to supply a signal to the pixel PXL and a power line configured to supply a common voltage (e.g., VDD, VSS, or the like) to the pixel PXL may be further disposed in the display panel 110.

The pixel PXL may include a pixel circuit configured to receive the data signal and the scan signal. The pixel circuit may include one or more thin-film transistors. The pixel circuit may include one or more capacitors. The pixel PXL may emit light corresponding to a level of an inputted data signal. In an embodiment, the pixel PXL may include a light emitting element (e.g., an organic light emitting element, an inorganic light emitting element, or the like) configured to emit light.

A light receiving area LRA may be provided in the pixel component 112. The light receiving area LRA may be an area provided to receive light. In an embodiment, the pixel PXL may not be disposed in the light receiving area LRA. In another embodiment, a density at which the pixels PXL are disposed in the light receiving area LRA may be lower than that in a peripheral area thereof (e.g., in other areas of the pixel component 112). Referring to FIG. 1, the light receiving area LRA may be disposed in the pixel component 112. In other embodiments, however, the light receiving area LRA may be disposed in an edge area (e.g., a notch area) of the pixel component 112. A light receiving device, which may be an image capturing device, such as a camera, an image sensor, or the like, a detecting sensor, such as a proximity sensor, an illuminance sensor, or the like, may be disposed to overlap the light receiving area LRA (e.g., in a third direction or a Z-axis direction).

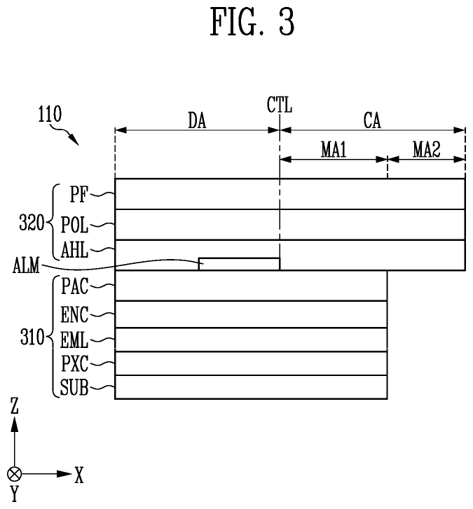

The dummy 114 is disposed around the pixel component 112. The dummy 114 may be separated and removed from the pixel component 112. Referring to FIG. 1, the dummy 114 may be formed by cutting the display panel 110 along a cutting line (e.g., a preset or predetermined cutting line) CTL. The dummy 114 may include a polarization structure. The polarization structure will be described in more detail below with reference to FIG. 3.

One or more integrated circuits may be mounted on the circuit board 120. The integrated circuits may be configured to generate and/or output signals (e.g., a data signal, a scan signal, and the like) to be inputted to the pixel PXL. The integrated circuits may be configured to generate and/or output voltages (e.g., VDD, VSS, and the like) to be inputted to the pixel PXL. The integrated circuits may include, for example, a source driver integrated circuit (SDIC), a timing controller (T-CON), a power management integrate circuit (PMIC), and the like. The circuit board 120 may include a printed circuit board (PCB), a flexible printed circuit board (FPCB), or the like.

The circuit board 120 may be directly connected to the pixel component 112 for example, by a bonding method or the like. In an embodiment, the circuit board 120 may be connected to the pixel component 112 by a separate electrical connector (e.g., a flexible printed circuit (FPC) or a flexible flat cable (FFC)). In the following description, embodiments pertaining to the connection between the circuit board 120 and the pixel component 112 may embrace not only an embodiment in which the circuit board 120 and the pixel component 112 are directly connected to each other but also an embodiment in which the circuit board 120 and the pixel component 112 are indirectly connected to each other by an electrical connector.

The dummy 114 may be formed after the pixel component 112 and the circuit board 120 are connected to each other. For example, the pixel component 112 and the circuit board 120 may be connected to each other, and the dummy 114 may be formed by cutting the display panel 110 along the cutting line CTL. The dummy 114 may be removed from the display panel 110 after the pixel component 112 and the circuit board 120 are connected to each other.

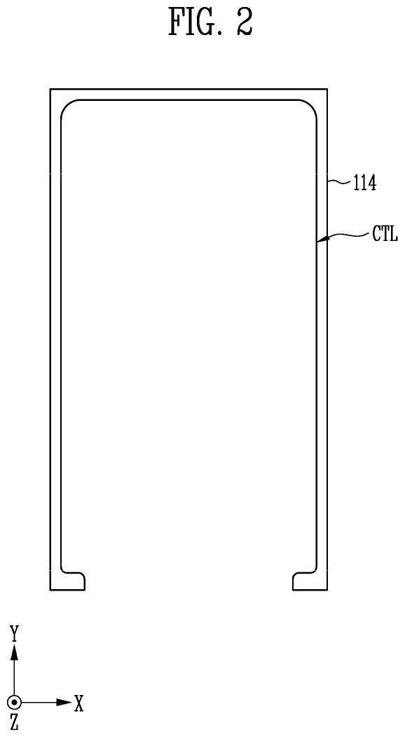

FIG. 2 illustrates the dummy 114 according to an embodiment of the present disclosure.

Referring to FIG. 2, the dummy 114 may be formed through a cutting operation along the cutting line CTL. The dummy 114 should have a small size to reduce waste and cost. The dummy 114 may have a small width in the first direction (e.g., the X-axis direction). The dummy 114 may have a small width in the second direction (e.g., the Y-axis direction).

Referring to FIG. 2, the dummy 114 may be integrally formed, but embodiments of the present disclosure are not limited thereto. In another embodiment, the dummy 114 may be divided into (or may include) two or more pieces.

After the cutting operation, the dummy 114 needs to be separated and removed from the pixel component 112 (see, e.g., FIG. 1).

FIG. 3 illustrates a sectional view of the display device shown in FIG. 1 taken along the line I-I′.

Referring to FIG. 3, the display device 100, according to an embodiment of the present disclosure, may include a display structure 310 and a polarization structure 320. The polarization structure 320 may be disposed on the display structure 310.

The pixel component 112 (see, e.g., FIG. 1) may include the display structure 310 and the polarization structure 320. The dummy 114 (see, e.g., FIG. 1) may include the polarization structure 320 but may not include the display structure 310.

Referring to FIG. 3, the display structure 310 may include a base substrate SUB, a pixel circuit layer PXC, a light-emitting-element layer EML, an encapsulation layer ENC, and the like.

The base substrate SUB may include a base layer including a polymer resin and a barrier layer formed of an inorganic insulating layer. For example, the base substrate SUB may include a first base layer, a first barrier layer, a second base layer, a second barrier layer, and the like, which are successively (or sequentially) stacked. The first base layer and the second base layer each may include polyimide, polyethersulfone, polyarylate, polyetherimide, polyethylene naphthalate, polyethylene terephthalate, polyphenylene sulfide, polycarbonate, cellulose triacetate, cellulose acetate propionate, and/or the like. The first barrier layer and the second barrier layer may include an inorganic insulating material, such as silicon oxide, silicon oxynitride, and/or silicon nitride. The base substrate SUB may be flexible.

The pixel circuit layer PXC may be disposed on the base substrate SUB. The pixel circuit layer PXC may include the pixel circuit described above. At least one thin-film transistor TFT and at least one storage capacitor Cst may be disposed in the pixel circuit layer PXC. The pixel circuit layer PXC may include not only a pixel circuit but also a buffer layer, a gate insulating layer, an interlayer insulating layer, a planarization insulating layer, and the like, which are disposed under and/or over components of the pixel circuit.

The buffer layer may reduce or prevent permeation of foreign material, water, or external air from (or through) the bottom of the base substrate SUB. The buffer layer may provide a planarization surface (e.g., a planar surface) on (or at an upper surface of) the base substrate SUB. The buffer layer may include an inorganic insulating material, such as silicon oxide, silicon oxynitride, or silicon nitride. The buffer layer may have a single-layer structure or multilayer structure including the foregoing material.

A thin-film transistor may be disposed on the buffer layer. The thin-film transistor may include a semiconductor layer, a gate electrode, a drain electrode, and a source electrode.

The semiconductor layer may include poly-crystalline silicon. The semiconductor layer may include single-crystal silicon. The semiconductor layer may include amorphous silicon (a-Si). The semiconductor layer may include an oxide semiconductor. The semiconductor layer may include an organic semiconductor or the like. The semiconductor layer may have a channel area, a drain area disposed on one side of the channel area, and a source area disposed on the other (e.g., the opposite) side of the channel area.

The gate electrode may overlap (e.g., may be vertically aligned with) the channel area. The gate electrode may include a low-resistance metal material. The gate electrode may include a conductive material including molybdenum (Mo), aluminum (Al), copper (Cu), titanium (Ti), or the like. The gate electrode may have a single-layer structure or multilayer structure including the foregoing material.

A first gate insulating layer may be disposed between the semiconductor layer and the gate electrode. The first gate insulating layer may include inorganic insulating material, such as silicon oxide (e.g., SiO₂), silicon nitride (e.g., SiNₓ) (x being a positive number), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnO₂).

A second gate insulating layer may be provided to cover the gate electrode.

The second gate insulating layer may include inorganic insulating material, such as silicon oxide (e.g., SiO₂), silicon nitride (e.g., SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnO₂), in a manner similar to that of the first gate insulating layer.

An upper electrode of the storage capacitor may be disposed over the second gate insulating layer. The upper electrode may overlap the gate electrode disposed thereunder. The gate electrode and the upper electrode that overlap each other with the second gate insulating layer interposed therebetween may form a storage capacitor. The gate electrode may act as a lower electrode of the storage capacitor.

The upper electrode may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu). The upper electrode may have a single layer structure or multilayer structure including the foregoing material.

The interlayer insulating layer may cover the upper electrode. The interlayer insulating layer may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), zinc oxide (e.g., ZnO₂), and/or the like. The interlayer insulating layer may include a single-layer structure or multilayer structure including the foregoing inorganic insulating material.

The drain electrode and the source electrode each may be disposed on the interlayer insulating layer. The drain electrode and the source electrode may be respectively electrically connected to the drain area and the source area through contact holes (e.g., contact openings) formed in the insulating layers provided thereunder. The drain electrode and the source electrode may include material having excellent conductivity. For example, each of the drain electrode and the source electrode may include a conductive material including molybdenum (Mo), aluminum (Al), copper (Cu), titanium (Ti), or the like. The drain electrode and the source electrode may have a single-layer structure or multilayer structure including the foregoing material. For example, each of the drain electrode and the source electrode may have a multilayer structure of Ti/Al/Ti.

A first planarization insulating layer may cover the drain electrode and the source electrode. A metal contactor may be disposed on the first planarization insulating layer. The metal contactor may include a conductive material including molybdenum (Mo), aluminum (Al), copper (Cu), titanium (Ti), or the like. The metal contactor may have a single-layer structure or multilayer structure including the foregoing material. A second planarization insulating layer may be disposed on the first planarization insulating layer. The second planarization insulating layer may cover the metal contactor. In an embodiment, the metal contactor may be omitted.

The first planarization insulating layer and the second planarization insulating layer may each include an organic insulating material, for example, a general-purpose polymer, such as polymethylmethacrylate or polystyrene, a polymer derivative including a phenolic group, an acrylic polymer, an imide-based polymer, an aryl ether-based polymer, an amide-based polymer, a fluorinate polymer, a p-xylene-based polymer, a vinyl alcohol-based polymer, and a blend thereof.

The light-emitting-element layer EML may be disposed on the pixel circuit layer PXC. The light emitting element may be disposed in the light-emitting-element layer EML. For example, the light emitting element may include an organic light emitting diode (OLED), but embodiments of the present disclosure are not limited thereto. The light emitting element may include a pixel electrode, an intermediate layer, a counter electrode, and the like. The light emitting element may emit, for example, red, green, or blue light, or may emit red, green, blue, or white light.

The pixel electrode may be electrically connected to the thin-film transistor through contact holes (e.g., contact openings) formed in the second planarization insulating layer and the first planarization insulating layer. For example, the pixel electrode may be electrically connected to the thin-film transistor through the metal contactor disposed on the first planarization insulating layer. The pixel electrode may include a conductive oxide, such as indium tin oxide (ITO), indium zinc oxide (IZO), zinc oxide (ZnO), indium oxide (e.g., In₂O₃), indium gallium oxide (IGO), or aluminum zinc oxide (AZO). The pixel electrode may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In an embodiment, the pixel electrode may further include a layer formed of ITO, IZO, ZnO or In₂O₃ and is provided over and/or under the reflective layer.

A pixel defining layer may be disposed on the pixel electrode. The pixel defining layer may include a hole (e.g., an opening) through which at least a portion of an upper surface of the pixel electrode is exposed. The pixel defining layer may include organic insulating material and/or inorganic insulating material. In the pixel PXL (see, e.g., FIG. 1), the hole may define an emission area in which light is emitted from the light emitting element. For instance, a width of the hole in the pixel defining layer may correspond to that of the emission area. The pixel defining layer may include an organic insulating material. For example, the pixel defining layer may include at least one of polystyrene, polymethylmethacrylate, polyacrylonitrile, polyamide, polyimide, poly (aryl ether), heterocyclic polymer, parylene, epoxy, benzocyclobutene, a siloxane-based resin, and a silane-based resin.

The intermediate layer may include an emission layer formed to correspond to the pixel electrode. The emission layer may include high or low molecular weight organic light emitting material, which may emit a color of light. The emission layer may include an inorganic light emitting material or may include quantum dots.

The intermediate layer may include a first functional layer and a second functional layer, which are respectively disposed under and over the emission layer. The first functional layer may include, for example, a hole transport layer (HTL), a hole injection layer (HIL), and the like. The second functional layer may include an electron transport layer (ETL), an electron injection layer (EIL), and the like. The first functional layer and/or the second functional layer may be a common layer that is integrally formed to cover the entirety of the base substrate SUB in the same manner as that of the counter electrode, to be described below.

The counter electrode may be disposed on the pixel electrode and may overlap the pixel electrode. The counter electrode may include a conductive material having a low work function. For example, the counter electrode may include a light transmission layer (e.g., a transparent layer or a translucent layer) including silver (Ag), magnesium (Mg), aluminum (Al), platinum (Pt), palladium (Pd), gold (Au), nickel (Ni), neodymium (Nd), iridium (Ir), chrome (Cr), lithium (Li), calcium (Ca), or an alloy thereof. The counter electrode may further include, on the light transmission layer including the foregoing material, a layer formed of ITO, IZO, ZnO, or In₂O₃. The counter electrode may be a common layer that is integrally formed to cover the entirety of the base substrate SUB.

The encapsulation layer ENC may be disposed on the light-emitting-element layer EML. The encapsulation layer ENC may cover the light-emitting-element layer EML. The encapsulation layer ENC may include at least one inorganic encapsulation layer and at least one organic encapsulation layer. For example, the encapsulation layer ENC may include a first inorganic encapsulation layer, an organic encapsulation layer, and a second inorganic encapsulation layer. The first inorganic encapsulation layer, the organic encapsulation layer, and the second inorganic encapsulation layer may be successively (or sequentially) stacked.

The first inorganic encapsulation layer and the second inorganic encapsulation layer may each include one or more inorganic materials from among aluminum oxide, titanium oxide, tantalum oxide, hafnium oxide, zinc oxide, silicon oxide, silicon nitride, and silicon oxynitride.

The organic encapsulation layer may include a polymer-based material. The polymer-based material may include an acrylic resin, an epoxy resin, polyimide, polyethylene, and the like. For example, the organic encapsulation layer may include acrylate. The organic encapsulation layer may be formed by curing a monomer or applying a polymer. The organic encapsulation layer may have light transmissive properties. Hence, the pixel PXL (see, e.g., FIG. 1) may emit light.

In an embodiment, a passivation layer PAC may be disposed on the encapsulation layer ENC. The passivation layer PAC may include a thermosetting resin.

The polarization structure 320 may be disposed on the encapsulation layer ENC or on the passivation layer PAC. The polarization structure 320 may cover at least a portion of the display area DA. The polarization structure 320 may prevent external light that is incident on the display panel 110 from being reflected.

The polarization structure 320 may include an adhesive layer AHL, a polarization layer POL, and a passivation film (or a protective film) PF. The polarization structure 320 may be disposed on the display structure 310 in the form of a film.

The adhesive layer AHL may be configured to attach the polarization structure 320 to the display structure 310. The adhesive layer AHL may have adhesiveness on both sides thereof (e.g., an upper surface and a lower surface). The adhesive layer AHL may have light transmissive properties. The adhesive layer AHL may include an optically clear adhesive (OCA).

The polarization layer POL may include a linear polarization layer and a phase difference layer. The linear polarization layer may convert natural light or arbitrarily polarized light to linearly polarized light. The linearly polarized light may mitigate reflection of external light. The phase difference layer may shift the phase of light that is incident on the phase difference layer by λ/4. Because the phase difference layer shifts the phase of the incident light by λ/4, linearly polarized light may be changed to circularly polarized light, or circularly polarized light may be changed to linearly polarized light. A polarizing axis of the phase difference layer may be inclined by 45° to a polarizing axis of the linear polarization layer.

The passivation film PF may be configured to protect the polarization layer POL provided thereunder. An adhesive layer (e.g., an adhesive film) may be interposed between the passivation film PF and the polarization layer POL.

The polarization structure 320 may be cut along the cutting line CTL. Referring to FIG. 3, the adhesive layer AHL, the polarization layer POL, and the passivation film PF may be cut along the cutting line CTL. An internal area (e.g., the display area DA) of the cut polarization structure 320 may correspond to the pixel component 112 (see, e.g., FIG. 1) described above. An external area (e.g., a cutting area CA) of the cut polarization structure 320 may correspond to the dummy 114 (see, e.g., FIG. 1) described above.

The cutting line CTL may be disposed more inside than one side end of the display structure 310 (e.g., the cutting line CTL may be over the display structure 310). For example, the cutting area CA may include a first margin area MA1, in which the polarization structure 320 is disposed to overlap the display structure 310, and a second margin area MA2, in which the polarization structure 320 and the display structure 310 are disposed not to overlap each other (e.g., at where the polarization structure 320 extends beyond an edge of the display structure 310). Because the polarization structure 320 corresponding to the cutting area CA is removed, the uppermost layer (e.g., the passivation layer PAC, the encapsulation layer ENC, or the like) of the display structure 310 may be exposed.

To guide a cutting position of the polarization structure 320, the display panel 110 may further include an align mark (or alignment mark) ALM. The align mark ALM may be positioned in a peripheral area of the cutting line CTL or an area overlapping the cutting line CTL. Although, for example, the align mark ALM may be positioned on the encapsulation layer ENC, embodiments of the present disclosure are not limited thereto.

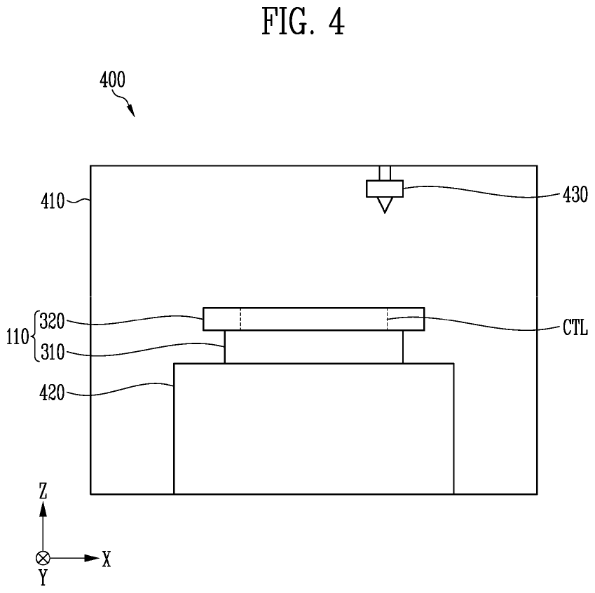

FIG. 4 illustrates a display panel cutting system 400 according to an embodiment of the present disclosure.

Referring to FIG. 4, the display panel cutting system 400, according to an embodiment of the present disclosure, may include a cutting room 410, a first stage 420, and a laser device 430.

The first stage 420 and the laser device 430 may be provided in the cutting room 410. A process of cutting the display panel 110 may be performed in the cutting room 410.

The display panel 110 may be seated on the first stage 420. The display device 100, which is seated on the first stage 420, may include the display structure 310 and the polarization structure 320. The display panel cutting system 400, according to an embodiment of the present disclosure, may further include an image capturing device configured to obtain an image of the align mark ALM (see, e.g., FIG. 3) described above. For example, the display panel 110 may be precisely aligned on the first stage 420 based on the align mark ALM read out from (e.g., identified in) the image captured by the image capturing device.

The laser device 430 may cut the polarization structure 320 along the cutting line CTL. The laser device 430 may cut the polarization structure 320 to a certain depth. For instance, using a half etching technique, the laser device 430 allows a certain thickness of the polarization structure 320 to remain rather than completely cutting (e.g., rather than cutting entirely through) the polarization structure 320. Hence, the display structure 310 provided under the polarization structure 320 may not be damaged. However, embodiments of the present disclosure are not limited thereto, and the laser device 430 may completely cut (e.g., may cut entirely through) the polarization structure 320.

Light irradiated from the laser device 430 cuts the polarization structure 320. There is no limit in wavelength of the light irradiated from the laser device 430 as long as it can cut the polarization structure 320.

The laser device 430 may move in the cutting room 410. For example, the laser device 430 may move along the cutting line CTL illustrated in FIG. 2 to form the dummy 114.

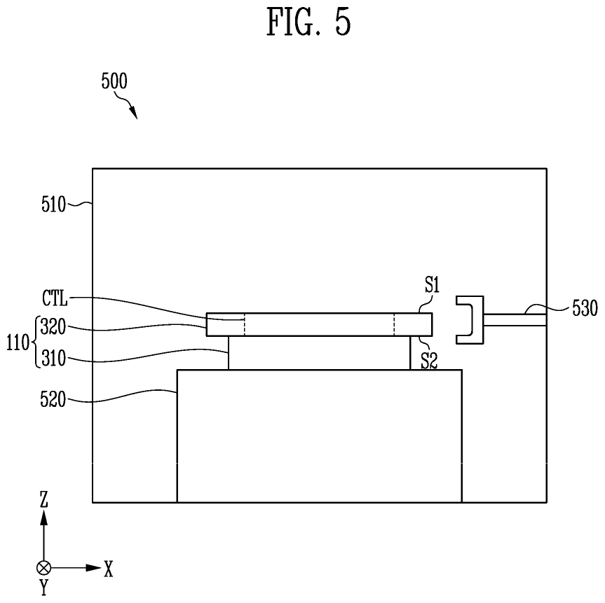

FIG. 5 illustrates a dummy removal system 500 according to an embodiment of the present disclosure.

Referring to FIG. 5, the dummy removal system 500, according to an embodiment of the present disclosure, may include a gripping room 510, a second stage 520, and a robot arm 530.

The second stage 520 and the robot arm 530 may be provided in the gripping room 510. In an embodiment, the cutting room 410 (see, e.g., FIG. 4) described above may be used as (or may be the same as) the gripping room 510. Although in the following description it is assumed that the cutting room 410 and the gripping room 510 are different rooms (or areas), embodiments of the present disclosure are not limited thereto.

The display panel 110 may be seated on the second stage 520. The display panel 110 seated on the second stage 520 may include the display structure 310 and the polarization structure 320. The display panel 110 seated on the second stage 520 may be obtained by performing the above-described cutting process. The dummy removal system 500, according to an embodiment of the present disclosure, may further include an image capturing device to obtain an image of the display panel 110 seated on the second stage 520. For example, the display panel 110 may be precisely aligned on the second stage 520 based on a position read out from the image captured by the image capturing device.

The robot arm 530 may be configured to remove the polarization structure 320 cut along the cutting line CTL from the display structure 310. The robot arm 530 may move toward and contact a first surface (or an upper surface) S1 and a second surface (or a lower surface) S2 of the polarization structure 320 (e.g., of the dummy 114) and grip the polarization structure 320.

The second surface S2 of the polarization structure 320 (e.g., the dummy 114) may correspond to the lower surface of the adhesive layer AHL (see, e.g., FIG. 3). Because the second surface S2 is adhesive, the dummy 114 may adhere to the robot arm 530 and may not be easily removed therefrom or may be removed therefrom at an undesired position.

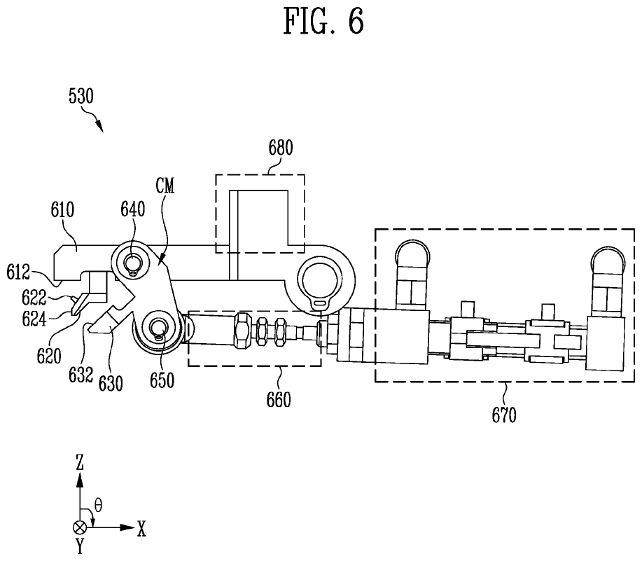

FIG. 6 illustrates the robot arm 530 shown in FIG. 5 according to an embodiment of the present disclosure.

The robot arm 530, according to an embodiment of the present disclosure, may include a first gripper 610, a stopper 620, and a second gripper 630.

The robot arm 530, according to various embodiments of the present disclosure, may further include a first rotator 640, a second rotator 650, a connector CM, a cylinder 660, a cylinder controller 670, a movable component 680, and the like.

Hereinafter, the robot arm 530, according to an embodiment of the present disclosure, will be described with reference to FIGS. 1 to 6.

The first gripper 610 may have a first contact surface 612. The first contact surface 612 may contact the first surface S1 of the dummy 114.

The second gripper 630 may have a second contact surface 632. The second contact surface 632 may contact the second surface S2 of the dummy 114. For example, the second contact surface 632 may move toward the first contact surface 612 so that the first gripper 610 and the second gripper 630 can grip the dummy 114. The dummy 114 may be attached to (e.g., adhered to) the second gripper 630 (or may be supported on the second gripper 630).

The stopper 620 may include a pin 622. The stopper 620 may have a pin support surface 624. The pin 622 may protrude from the pin support surface 624 toward the first contact surface 612. The stopper 620 may be located to overlap a movement path (e.g., a rotation path) of the second gripper 630. The pin 622 may support the second surface S2 of the dummy 114 and may remove the dummy 114 from the second gripper 630. Because a surface area at where the pin 622 contacts the second surface S2 of the dummy 114 is very small compared to a surface area at where the second contact surface 632 contacts the second surface S2, the dummy 114 may be more easily removed from the stopper 620.

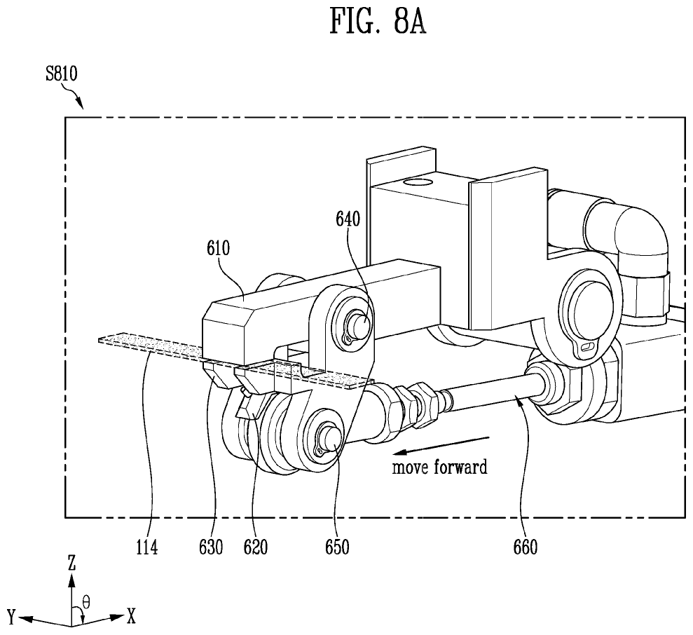

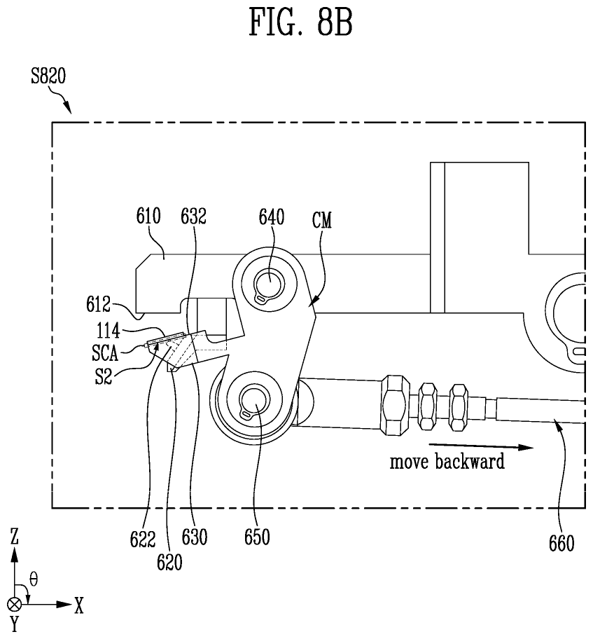

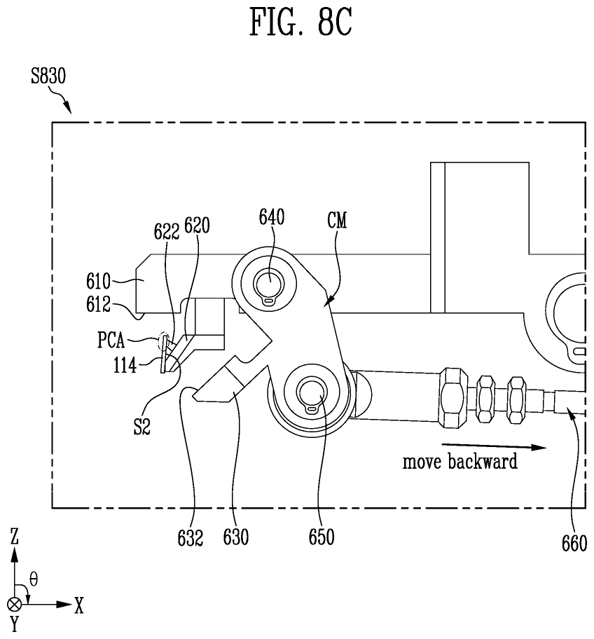

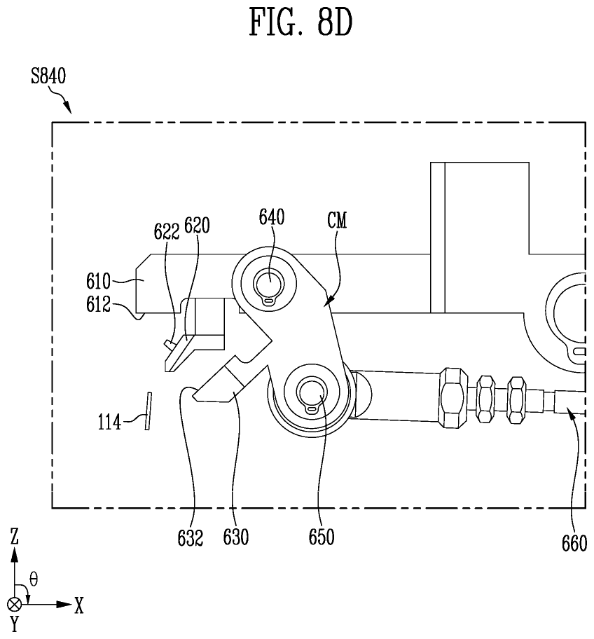

The operation of removing the dummy 114 from the second gripper 630 will be described in detail with reference to FIGS. 8A to 8D.

The first rotator 640 may be connected to the first gripper 610. The first rotator 640 may be coupled to the connector CM. The first rotator 640 may include a component (e.g., a bearing or the like) for providing rolling force (e.g., for providing a moment force) to rotate the connector CM. The connector CM may be rotated in a direction (e.g., the direction indicated by θ in FIG. 6) by the first rotator 640.

The connector CM may rotate on (or may rotate about) the first rotator 640. The second gripper 630 may be connected to the connector CM. For example, the second gripper 630 may diverge from (e.g., may protrude from) the connector CM. As the connector CM rotates, the second gripper 630 also rotates. The second gripper 630 may rotate on (or may rotate along with or according to) the first rotator 640.

The second rotator 650 may be coupled to the connector CM. The second rotator 650 may include a component (e.g., a bearing or the like) for providing rolling force (e.g., for providing a moment force) to rotate the connector CM. The second rotator 650 is connected to the cylinder 660. Forward movement or backward movement of a piston disposed in the cylinder 660 may be converted to rotational motion of the connector CM by the second rotator 650.

The cylinder 660 may include the piston. The piston may move forward or backward in a cylindrical structure. The movement of the piston may be controlled by the cylinder controller 670. The cylinder 660 may be implemented as a hydraulic type, a pneumatic type, or the like. The type of the cylinder 660 is not particularly limited.

The cylinder controller 670 may be configured to control pressure in the cylinder 660. Depending on the type of the cylinder 660, the cylinder controller 670 may control hydraulic pressure, pneumatic pressure, or the like in the cylinder 660.

The movable component 680 may be configured to control overall movement of the robot arm 530. For example, a position at which the dummy 114 is removed from the robot arm 530 may be adjusted by movement of the movable component 680. For instance, the dummy 114 may be removed from the second gripper 630 at a position to which the robot arm 530 is moved by the movable component 680.

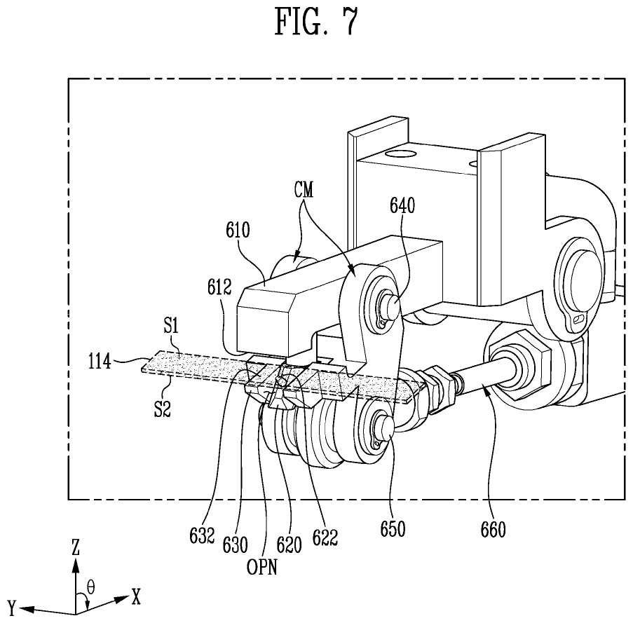

FIG. 7 is a diagram illustrating the dummy 114 supported on the second gripper 630.

Referring to FIG. 7, the second surface S2 of the dummy 114 is attached to (e.g., adhered to) the second contact surface 632 of the second gripper 630. Hence, the dummy 114 is supported on the second gripper 630. The dummy 114 may be removed from the second gripper 630 by the stopper 620.

For example, the piston in the cylinder 660 may move backward to move the second gripper 630 in a direction away from the first gripper 610. The stopper 620 passes through an opening OPN formed in the second gripper 630.

As illustrated in FIG. 7, the opening OPN may be formed by opening one edge (e.g., an edge at a position corresponding to a negative (−) X-axis direction) of the second contact surface 632. However, in an embodiment, the opening OPN may be an open area enclosed by (or closed by a surface of) the second contact surface 632.

The pin 622 may contact the second surface S2 of the dummy 114. The dummy 114 may be removed from the second gripper 630 and supported on the stopper 620. Because the surface area with which the pin 622 contacts the second surface S2 is very small, the dummy 114 may be easily removed from the stopper 620 in the direction of gravity.

Based on the above-mentioned principle, defects that may result from attachment of the dummy 114 to the second gripper 630 may not occur or may be avoided.

FIGS. 8A to 8D are diagrams illustrating steps of a method of driving the dummy removal system 500 according to an embodiment of the present disclosure.

The method of driving the dummy removal system, according to an embodiment of the present disclosure, may include a gripping step S810, a second gripper supporting step S820, a stopper supporting step S830, a dummy removal step S840, and the like.

Referring to FIG. 8A, at the gripping step S810, the piston in the cylinder 660 moves forward. Hence, the second gripper 630 moves (e.g., rotates) in a direction toward the first gripper 610. At this step, the dummy 114 is gripped by (e.g., is gripped between) the first gripper 610 and the second gripper 630.

Referring to FIG. 8B, at the second gripper supporting step S820, the piston in the cylinder 660 moves backward. Hence, the second gripper 630 moves (e.g., rotates) in a direction away from the first gripper 610. The dummy 114 may move with the second gripper 630 because the second surface S2 is attached to (e.g., adhered to) the second contact surface 632 of the second gripper 630. An area at where the dummy 114 contacts the second gripper 630 may be referred to as a surface contact area SCA.

Referring to FIG. 8C, at the stopper supporting step S830, the piston in the cylinder 660 moves backward. The dummy 114 is stopped by the pin 622 and removed from the second gripper 630. An area at where the dummy 114 contacts the pin 622 may be referred to as a point contact area PCA.

Referring to FIG. 8D, at the dummy removal step S840, the dummy 114 is removed from the stopper 620. Because a surface area of the point contact area PCA is much smaller than that of the surface contact area SCA, the dummy 114 may be easily removed from the stopper 620.

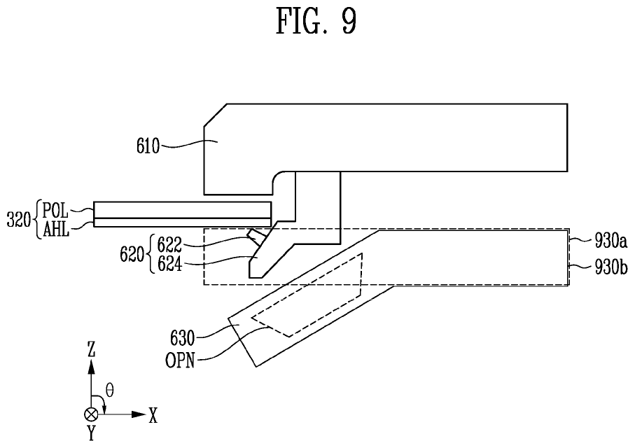

FIG. 9 is a schematic view illustrating a robot arm according to another embodiment of the present disclosure.

In the embodiment illustrated in FIG. 9, the stopper 620 is coupled and fastened to (e.g., is fixed to) the first gripper 610.

In the embodiment shown in FIG. 9, the passivation film PF (see, e.g., FIG. 3) of the polarization structure 320 is omitted, embodiments of the present disclosure are not limited thereto.

Referring to FIG. 9, the second gripper 630 is illustrated in a first state with reference to 930a, and the second gripper 630 is illustrated in a second state with reference to 930b. The second gripper 630 in the first state (930a) may correspond to the position of the second gripper 630 at the gripping step S810 (see, e.g., FIG. 8A) described above. The second gripper 630 in the second state (930b) may correspond to the position of the second gripper 630 at the stopper supporting step S830 (see, e.g., FIG. 8C) described above. In other words, the stopper 620 may be positioned along a movement path of the second gripper 630. In more detail, the stopper 620 may be positioned in a path along which the opening OPN in the second gripper 630 moves. Thereby, the polarization structure 320 (e.g., the dummy 114) may be removed from the second gripper 630 by the stopper 620.

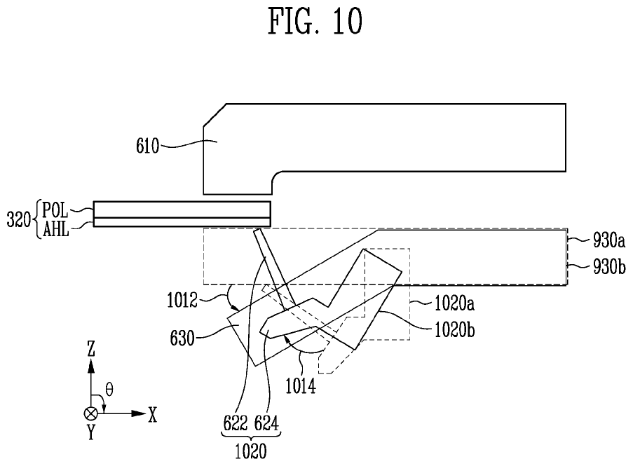

FIG. 10 is a schematic view illustrating a robot arm according to another embodiment of the present disclosure.

The embodiment illustrated in FIG. 10 includes a moving (e.g., rotating) stopper 1020. The stopper 1020 illustrated in FIG. 10 is similar to the stopper 620 illustrated in FIG. 6 in that the stopper 1020 includes a pin 622 and a pin support surface 624 and the pin 622 pushes the polarization structure 320 to remove the polarization structure 320 from the second gripper 630. The stopper 1020 illustrated in FIG. 10 is different from the stopper 620 illustrated in FIG. 6 in that the stopper 1020 is configured to rotate in a direction opposite to a rotational direction of the second gripper 630.

Referring to FIG. 10, the stopper 1020 may remove the polarization structure 320 (e.g., the dummy 114) from the second gripper 630 by rotating in a direction opposite to the rotational direction of the second gripper 630 to push the polarization structure 320 off of the second gripper 630.

For example, referring to FIG. 10, when the position of the second gripper 630 corresponds to the second gripper 630 in a first state (930a), the position of the stopper 1020 may correspond to the stopper 1020 in the first state (1020a). When the position of the second gripper 630 corresponds to the second gripper 630 in a second state (930b), the position of the stopper 1020 may correspond to the stopper 1020 in the second state (1020b).

When the second gripper 630 rotates in a first direction 1012, the stopper 1020 rotates in a second direction 1014 and pushes the polarization structure 320 to remove the polarization structure 320 from the second gripper 630.

The first direction 1012 and the second direction 1014 are opposite to each other. Referring to FIG. 10, when the first direction corresponds to a direction indicated by θ (e.g., a direction rotating from a positive (+) Z-axis to an X-Y plane), the second direction 1014 may refer to a direction corresponding to −θ (e.g., a direction rotating from a negative (−) Z-axis to the X-Y plane).

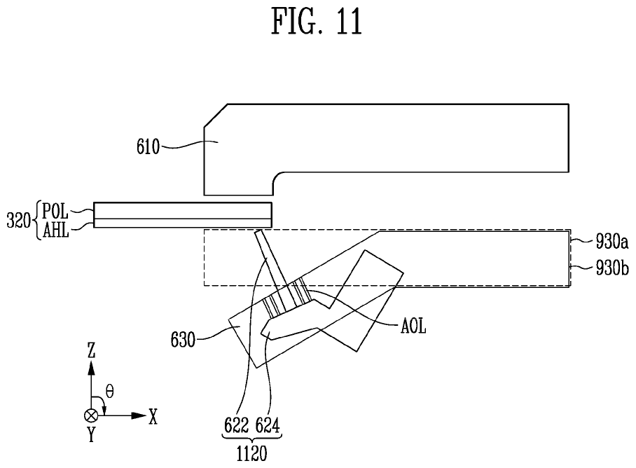

FIG. 11 is a schematic view illustrating a robot arm according to another embodiment of the present disclosure.

The embodiment illustrated in FIG. 11 corresponds to an embodiment in which the stopper 1120 is fixed in place at a position adjacent to the second gripper 630. The stopper 1120 illustrated in FIG. 11 is similar to the stopper 620 illustrated in FIG. 6 or the stopper 1020 illustrated in FIG. 10 in that the stopper 1120 includes a pin 622 and a pin support surface 624 and that the pin 622 pushes the polarization structure 320 to remove the polarization structure 320 from the second gripper 630. However, the stopper 1120 illustrated in FIG. 11 is different from the stopper 620 illustrated in FIG. 6 or the stopper 1020 illustrated in FIG. 10 in that the stopper 1120 is not connected to the first gripper 610 and is fixed in place in an area adjacent to the second gripper 630.

Referring to FIG. 11, the second gripper 630 may further include an air outlet AOL. The polarization structure 320 may be more easily removed from the second gripper 630 by discharging air through the air outlet AOL (e.g., by supplying air toward the polarization structure 320).

A robot arm, a dummy removal system including the robot arm, and a method of driving the dummy removal system according to embodiments of the present disclosure may easily remove a polarization structure of a display panel.

Although embodiments of the present disclosure have been disclosed herein for illustrative purposes, those skilled in the art will appreciate that various modifications, additions, and substitutions are possible without departing from the scope and spirit of the present disclosure as set forth in the accompanying claims and their equivalents.

What is claimed is:

1. A robot arm comprising:
a first gripper having a first contact surface;
a second gripper having a second contact surface corresponding to the first contact surface and an opening in the second contact surface; and
a stopper comprising a pin protruding toward the first gripper, the stopper being configured to pass through the opening in the second gripper.

2. The robot arm according to claim 1, further comprising:
a first rotator connected to the first gripper; and
a connector coupled to the first rotator such that a rotational direction of the connector is guided by the first rotator.

3. The robot arm according to claim 2, wherein the second gripper is connected to the connector.

4. The robot arm according to claim 2, wherein the second gripper is configured to rotate about the first rotator, and
wherein the pin arranged along a path along which the second gripper rotates.

5. The robot arm according to claim 2, further comprising:
a second rotator coupled to the connector; and
a cylinder configured to guide movement of the second rotator.

6. The robot arm according to claim 1, wherein the stopper is fixed to the first gripper.

7. The robot arm according to claim 1, wherein the stopper is configured to rotate in a direction opposite to a direction in which the second gripper rotates.

8. The robot arm according to claim 1, wherein the second gripper has an air outlet in the second contact surface.

9. A dummy removal system comprising:
a stage configured to receive a display panel, the display panel comprising a pixel component in a central portion thereof and a dummy around the pixel component, the dummy being cut from the display panel along a cutting line; and
a robot arm comprising a first gripper configured to contact a first surface of the dummy, a second gripper configured to contact a second surface of the dummy, and a stopper configured to pass through an opening in the second gripper.

10. The dummy removal system according to claim 9, wherein the display panel comprises a display structure and a polarization structure on the display structure, and
wherein the polarization structure comprises an adhesive layer, a polarization layer, and a passivation film sequentially stacked on each other.

11. The dummy removal system according to claim 10, wherein the polarization structure comprises a polarization film, and
wherein the dummy comprises the adhesive layer, the polarization layer, and the passivation film.

12. The dummy removal system according to claim 10, wherein the first surface is an upper surface of the passivation film, and the second surface is a lower surface of the adhesive layer,
wherein the first gripper has a first contact surface for contacting the upper surface of the passivation film, and
wherein the second gripper has a second contact surface for contacting the lower surface of the adhesive layer.

13. The dummy removal system according to claim 10, wherein the robot arm further comprises:
a first rotator connected to the first gripper; and
a connector coupled to the first rotator such that a rotational direction of the connector is guided by the first rotator, and
wherein the second gripper is connected to the connector.

14. The dummy removal system according to claim 13, further comprising:
a second rotator coupled to the connector; and
a cylinder configured to guide movement of the second rotator.

15. The dummy removal system according to claim 14, wherein the stopper comprises a pin protruding toward the first gripper,
wherein, as a piston in the cylinder moves forward, the second gripper moves toward the first gripper, and
wherein, as the piston in the cylinder moves backward, the second gripper moves toward the pin.

16. The dummy removal system according to claim 10, wherein the display structure comprises:
a base substrate;
a pixel circuit layer on the base substrate and comprising a thin-film transistor;
a light-emitting-element layer connected to the thin-film transistor and comprising a light emitting element and an emission layer; and
an encapsulation layer covering the light-emitting-element layer.

17. The dummy removal system according to claim 10, wherein the cutting line is more inside than one side end of the display structure.

18. A method of operating a dummy removal system comprising a robot arm, the method comprising:
seating a display panel on a stage, the display panel comprising a pixel component in a central portion thereof and a dummy around the pixel component, the dummy being formed by cutting the display panel along a cutting line;
a gripping operation comprising bringing a first surface of the dummy into contact with a first contact surface of a first gripper of the robot arm and bringing a second surface of the dummy into contact with a second contact surface of a second gripper of the robot arm;
a second gripper supporting operation comprising moving the second gripper away from the first contact surface with the dummy attached to the second gripper;
a stopper supporting operation comprising moving the second gripper through the stopper to support the dummy on a pin of the stopper and to remove the dummy from the second gripper; and
a dummy removal operation comprising removing the dummy from the pin in a direction of gravity.

19. The method according to claim 18, wherein the robot arm comprises:
a first rotator connected to the first gripper;
a connector coupled to the first rotator such that a rotational direction of the connector is guided by the first rotator, the second gripper being connected to the connector;
a second rotator coupled to the connector; and
a cylinder configured to guide movement of the second rotator,
wherein the gripping operation comprises moving a piston in the cylinder forward.

20. The method according to claim 19, wherein each of the second gripper supporting operation and the stopper supporting operation comprises moving the piston in the cylinder backward.
